(19) United States
(12) Patent Application Publication
(10) Pub. No.: US 2005/0057253 A1
(43) Pub. Date: Mar. 17, 2005

(54) Digital phosphor spectrum analyzer

(76) Inventors: Edward C. Gee, Portland, OR (US); Alfred K. Hillman, Banks, OR (US); Stephen D. Follettt, Tigard, OR (US); Richard A. Cameron, Portland, OR (US); Antti Sivula, Portland, OR (US)

Correspondence Address: TEKTRONIX, INC.;Francis I. Gray, MS 50 LAW, P.O. Box 500, Beaverton, OR, 97077, US

(21) Appl. No.: 10/655,513

(22) Filed: Sep. 3, 2003

(51) Int. Cl. G01R 31/00

(52) U.S. Cl. 324/409

(57) ABSTRACT

A digital phosphor spectrum analyzer (DPSA) uses a fast rasterization and decay process to emulate the look and feel of an analog phosphor display while improving the ratio of waveform acquisition to non-acquisition time. Multiple acquisitions of complex digital data for an input signal being analyzed across a frequency span are accumulated in a raster memory at a waveform update rate to produce a composite waveform. A decay function is applied to the composite waveform to produce a display waveform. The display waveform is viewed on a display device at a display update rate, resulting in the ability to see otherwise unobservable frequency characteristics of the input signal.

### BACKGROUND OF THE INVENTION

The present invention relates to spectrum analysis, and more particularly to a digital phosphor spectrum analyzer (DPSA) using fast rasterization and decay processing to emulate the look and feel of an analog phosphor display.

In a typical digital spectrum analyzer a signal being monitored is actually sampled during a very small percentage of time when presenting data to a user. For example a swept-frequency digital spectrum analyzer only observes signal content within a frequency range of a resolution bandwidth (RBW) filter at any given instant. For a digital spectrum analyzer with a sweep rate of 15 msec spanning 5 MHz in frequency with an RBW of 30 kHz and a waveform update rate of 30 waveforms per second, a specific frequency may be observed for less than 90 μsec [(0.015×3×10⁴)/5×10⁶] per sweep, or about 2.7 msec (9×10⁻⁵×30) in a one-second period, where each waveform represents a complete frequency span. Also a digital spectrum analyzer using digital intermediate-frequency (IF) down-conversion lacks the “look and feel” of an analog-type swept-frequency spectrum analyzer using a cathode ray tube (CRT) phosphor display, limiting a user's ability to see signal details that might otherwise be observable. See FIG. 1 which is a conventional single-sweep display for a digital spectrum analyzer according to the prior art.

A real-time or continuous-capture spectrum analyzer offers one solution to the first problem—the discontinuous monitoring of the signal at a given frequency—but doesn't address the analog “look and feel” desired by a significant percentage of users. Users still may not be able to observe low-level signals buried near the noise floor, see modulation details that are not obvious, or see pulsed spectra that might be masked by a higher amplitude wide-band signal. A spectrogram display—amplitude vs. frequency vs. time—also addresses the problem of observing faint signals that may not be discernible from the noise floor in a typical spectrum display. However, the spectrogram display has the limitation of assigning a relatively finite number of amplitude levels in a color-grading display scheme, and a common implementation is again limited by the percentage of time that the digital spectrum analyzer is actually sampling the signal since only a single acquisition waveform is displayed per waveform update.

Cumulative rasterization and decay of digitized data has been applied to digitizing oscilloscopes to mimic the effect of analog oscilloscope displays—specifically to mimic electron beam/phosphor effects from a CRT. These are applications used in amplitude versus time measurement devices. The challenge for a digital spectrum analyzer is to provide frequency transformation processing at a rate fast enough to mimic the look and feel of an analog, swept-spectrum CRT-based display.

What is desired is the application of cumulative rasterization and decay technology to a digital spectrum analyzer that has a very high waveform update rate to emulate the look and feel of an analog phosphor display while improving the ratio of waveform acquisition to non-acquisition time.

### BRIEF SUMMARY OF THE INVENTION

Accordingly the present invention provides a digital phosphor spectrum analyzer that uses fast rasterization and decay processing to emulate the look and feel of an analog phosphor display while improving the ratio of waveform acquisition to non-acquisition time. Multiple acquisitions of complex digital data for an input signal being analyzed across a frequency span are accumulated in a raster memory at a waveform update rate to produce a composite waveform or “frame.” A decay function is applied to the composite waveform to produce a display waveform. The display waveform is viewed on a display device at a frame or display update rate, resulting in the ability to see otherwise unobservable frequency characteristics of the input signal.

The objects, advantages and other novel features of the present invention are apparent from the following detailed description when read in conjunction with the appended claims and attached drawing.

### BRIEF DESCRIPTION OF THE SEVERAL VIEWS OF THE DRAWING

FIG. 1 is a graphic view of a conventional digital spectrum analyzer display.

FIG. 2 is a block diagram view of a typical digital down converter.

FIG. 3 is a block diagram view of a digital phosphor spectrum analyzer having a spectral processing engine according to the present invention.

FIG. 4 is a graphic view showing the relationship between a spectral waveform and its dot-mode rasterized representation.

FIG. 5 is a graphic view showing the relationship between a spectral waveform and its vector-mode rasterized representation.

FIG. 6 is a graphic view showing the relationship between power and frequency comparable to FIG. 1 for the digital phosphor spectrum analyzer according to the present invention.

FIG. 7 is a graphic view showing a constellation diagram display for the digital phosphor spectrum analyzer according to the present invention.

FIG. 8 is a graphic view showing an example of stepped frequency rasterization of a waveform.

### DETAILED DESCRIPTION OF THE INVENTION

A digital phosphor spectrum analyzer (DPSA) may be implemented in one of two forms—a parallel configuration using a “bank of filters” in the form of a fast discrete Fourier transform (DFT) or a swept configuration that is functionally similar to a traditional swept spectrum analyzer. In the parallel configuration channel characteristics are determined by a “window” applied to the digitized data prior to the DFT, the window being equivalent to a resolution bandwidth (RBW) filter. The acquisition time is determined by window length and sample rate. In the swept configuration the RBW filter may be implemented as a pair of finite impulse response (FIR) filters following a numerically controlled oscillator (NCO) in a digital down-converter (DDC), as shown in FIG. 2.

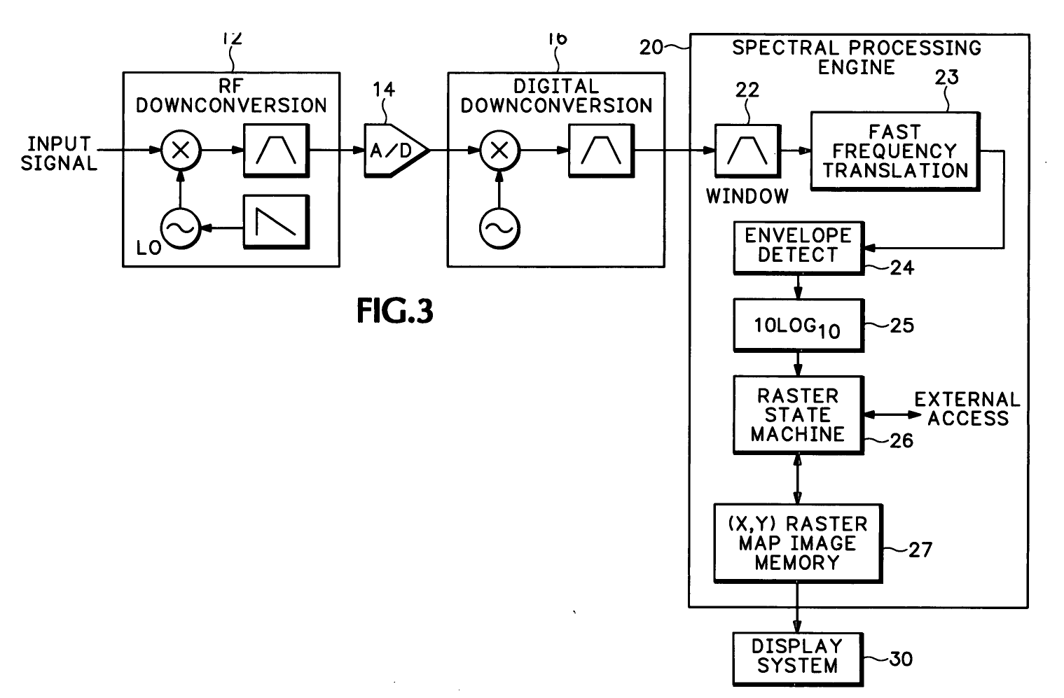

Referring now to FIG. 3 a digital phosphor spectrum analyzer (DPSA) is shown having a conventional RF down-converter 12 followed by an analog-to-digital (A/D) converter 14 and a conventional digital down-converter (DDC) 16. The resulting digitized data is then input to a spectral processing engine 20 which processes the data for display. The RF and digital down-converters 12, 16 are shown for completeness, but are not a direct part of the present invention. Down conversion, and the methods thereof, prior to the spectral processing engine 20 is optional. It is dependent upon the available A/D technology and the desired frequency coverage.

The spectral processing engine 20 has several key blocks. A windowing function 22 receives the time domain digitized data, such as complex I/Q data, from the DDC 16 or the A/D converter 14 to define observable channel characteristics, essentially serving as an RBW filter for a display window. A fast frequency translator 23 performs a DFT to convert the windowed time-domain samples from the windowing function 22 to the frequency domain. An envelop detector 24 calculates an amplitude (power) for each frequency location based on the complex data. The resulting data then optimally is passed through a logarithmic calculator 25 to convert to a logarithmic scale display as is conventionally used by a spectrum analyzer.

A raster state machine 26 includes optional vector processing, waveform pixel mapping (rasterization) and decay functions for the power versus frequency data. The rasterization process maps the complex data points into a pixel memory buffer 27 (raster map image) representing a waveform viewing or display window. Each location in the pixel memory buffer 27 has n-bits of intensity data. The mapping process is described below.

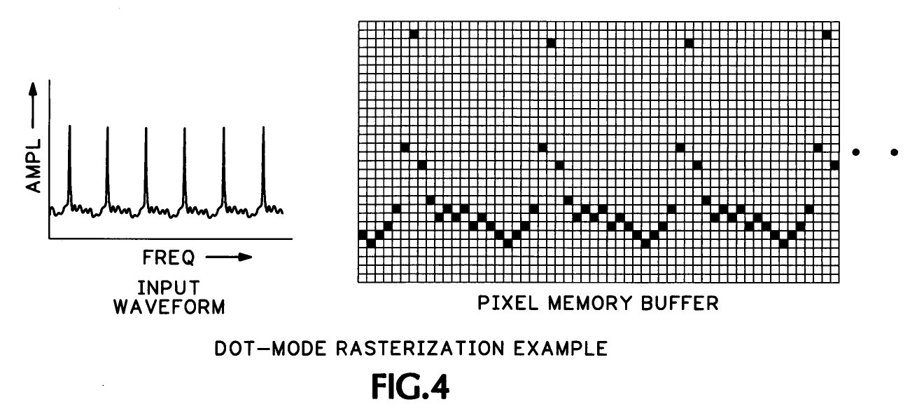

For each sample point in the input waveform the intensity value at the pixel address in the memory map corresponding to the complex data is increased by a user-configurable intensity attack value. This is referred to as point-by-point or dot-mode processing. An example of mapping a single waveform is shown in FIG. 4.

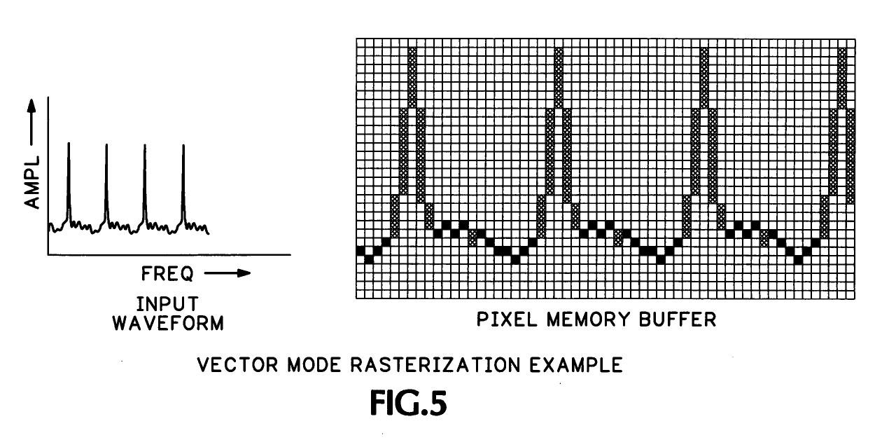

Optional vector processing may be used to effectively increase the perceived data rate over dot-mode processing to enhance the “analog feel” of the waveforms without actually increasing the waveform update rate in the spectral processing engine 20. In this mode vectors, or sparse vectors as taught in U.S. Pat. No. 6,104,374, are calculated prior to the rasterization function. Instead of having blank pixels between waveform points, calculated vectors fill in pixel-by-pixel, or sparse pixels, between consecutive waveform points. The configurable intensity attack value—intensity increment—is evenly spread between each of the calculated pixel points, i.e., the intensity attack value is divided by the vector distance. This simulates slew-rate variations in intensity that are observable on an analog CRT phosphor display. An example of vector-mode processing is shown in FIG. 5.

A large number of waveforms are accumulated in the pixel memory buffer 27 to create a “frame” of data. The frame represents the display update period. The raster accumulation in the frame provides an intensity-based history of the complex data captured through multiple acquisitions, yielding an analog-like feel. Frames are transferred to a measurement device display system 30 at a defined frame or display update rate.

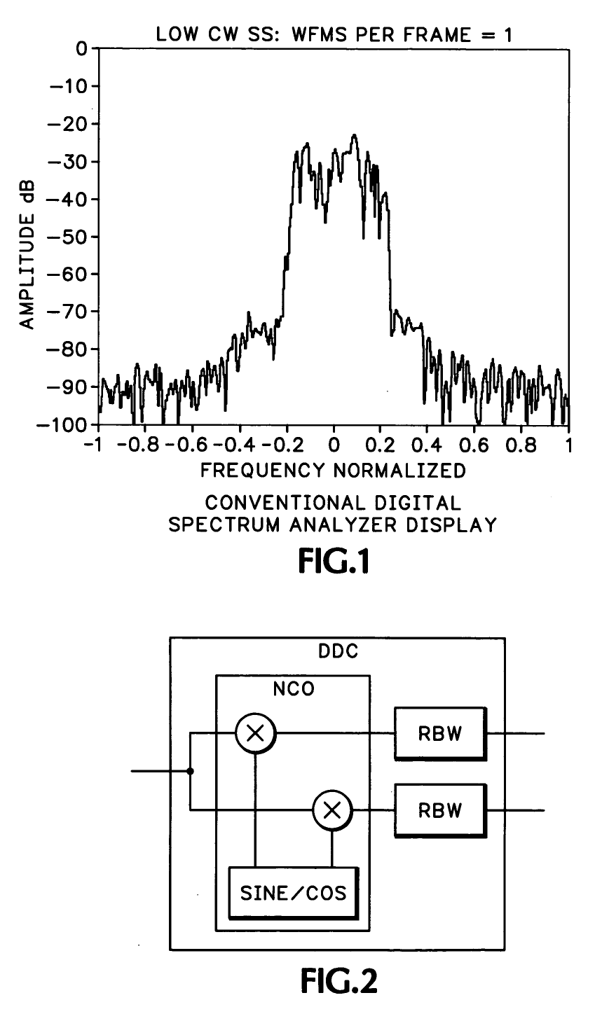

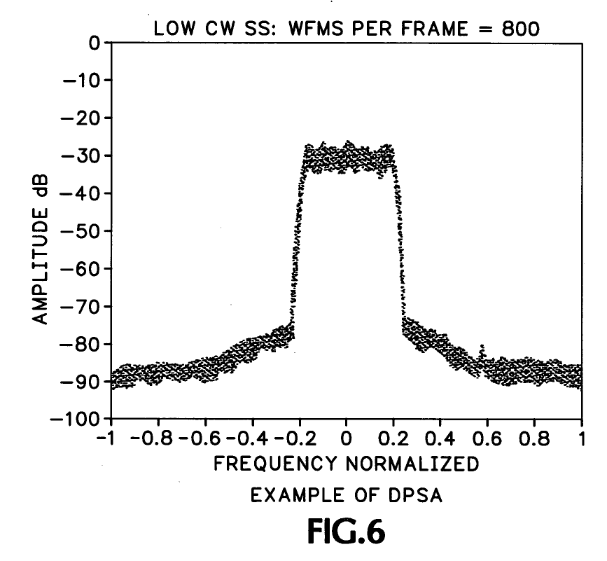

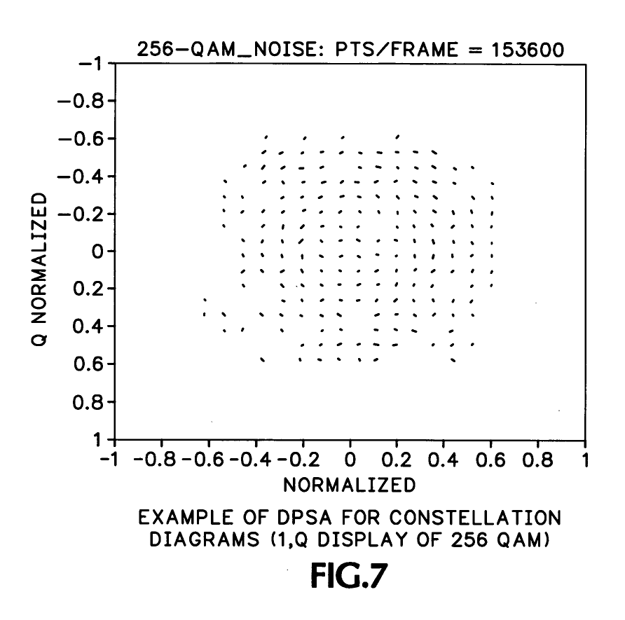

The decay function in the raster state machine 26 sweeps through the entire pixel map once per frame to decrement the intensity value at every location by a configurable value—a minimum intensity value of zero is enforced. The decay function may use any type of decay rate, such as exponential, linear, quadratic, S-shaped or arbitrary. Two of many possible methods of implementing the decay are described below. The first method uses a process that decrements the memory locations in “dead time” between waveform updates, and halts as new waveforms are rasterized into the pixel memory buffer 27. Using this method multiple “sections” of the buffer 27 are decremented at different times, but the entire buffer decay is completed once per frame update. The second method uses a process that decrements the memory locations across the entire buffer 27 in one continuous process, holding off new waveform updates into the buffer until the frame decay process is complete. An example of a display for power versus frequency is shown in FIG. 6, where a spurious signal is shown that is not apparent in the corresponding single sweep view of FIG. 1. Further FIG. 7 shows a representative constellation display for a communications signal as produced by the DPSA.

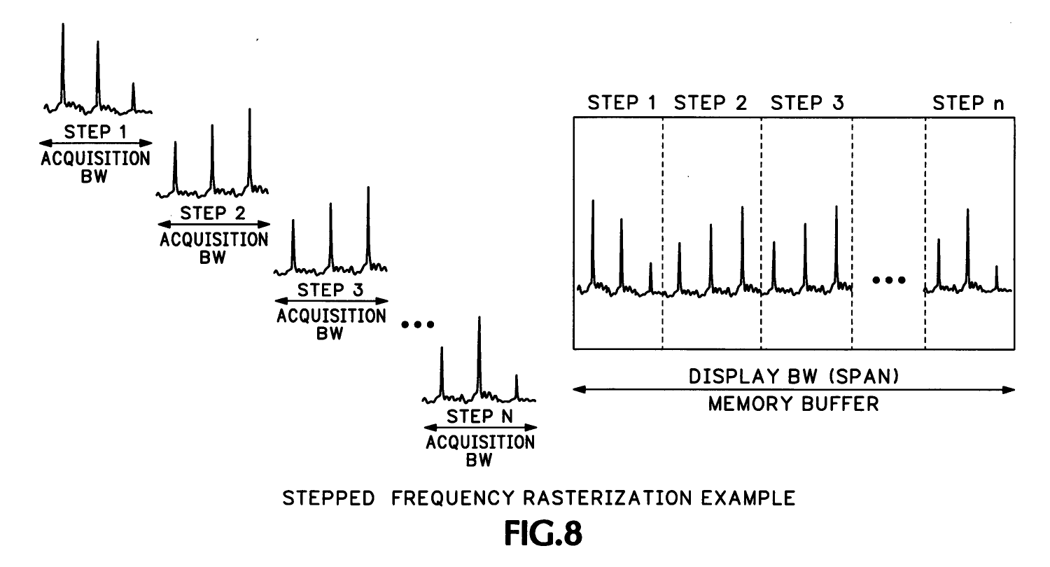

For frequency spans that are wider than the bandwidth of the down-conversion system 12, 16 the frequency may be “stepped” to fill the data within a section of the pixel map frame representing the frequency covered by that step, as shown in FIG. 8. In the limiting case of an infinite number of steps a local oscillator frequency in the RF down-converter 12 is swept across the frequency range of interest as described in U.S. Pat. No. 4,890,237. Using this model multiple amplitude “points”—y-values—are accumulated at a single frequency location—x-values—in the raster map image. If the duration of the frequency sweep is longer than the frame period update, the decay state may be held off until the sweep of the entire frequency span is complete.

Thus the present invention provides application of fast rasterization and decay processing to a digital spectrum analyzer to emulate the look and feel of an analog phosphor display by compositing a number of acquired waveforms across a frequency span into a single raster image buffer at high speeds, applying a decay function to the composite waveform, and then shipping the resulting composite waveform to a display system at a frame update rate to provide a phosphor-like display and a significantly higher ratio of waveform acquisition to non-acquisition time that enables users to observe frequency events that might otherwise be unobservable.

1. A digital phosphor spectrum analyzer comprising:
means for acquiring digital data from an input signal being analyzed across a frequency span;
means for accumulating multiple acquisitions of the digital data across the frequency span at a waveform update rate to form a composite waveform;
means for decaying the composite waveform at regular intervals to produce a display waveform; and
means for displaying the display waveform at a display update rate whereby the display waveform emulates the look and feel of an analog phosphor display.

2. The digital phosphor spectrum analyzer as recited in claim 1 wherein the digital data represents power at discrete frequencies within the frequency span.

3. The digital phosphor spectrum analyzer as recited in claim 1 wherein the display waveform represents an amplitude versus frequency spectrum for the input signal within the frequency span.

4. The digital phosphor spectrum analyzer as recited in claim 1 wherein the digital data represents amplitude and phase in a modulation domain within the frequency span.

5. The digital phosphor spectrum analyzer as recited in claim 4 wherein the display waveform represents a constellation display for the input signal within the frequency span.

6. The digital phosphor spectrum analyzer as recited in claim 1 wherein the digital data represents amplitude and code within the frequency span.

7. The digital phosphor spectrum analyzer as recited in claim 6 wherein the display waveform represents a code domain display for the input signal within the frequency span.

8. The digital phosphor spectrum analyzer as recited in any one of claims 1-7 wherein the decaying means uses a decay function selected from the group consisting of an exponential decay rate, a linear decay rate, a quadratic decay rate, an S-curve decay rate and an arbitrary decay rate.

9. The digital phosphor spectrum analyzer as recited in claim 8 wherein the decaying means is applied to the composite waveform between acquisitions of the digital data in a segmented manner such that the decay function is completed for the composite waveform at the display update rate.

10. The digital phosphor spectrum analyzer as recited in claim 8 wherein the decaying means is applied to the composite waveform after the multiple acquisitions of the digital data such that the decay function is completed for the composite waveform at the display update rate.

11. The digital phosphor spectrum analyzer as recited in claim 8 wherein the acquisitions occur over sequential sub-intervals of the frequency span.

12. The digital phosphor spectrum analyzer as recited in claim 11 wherein the decaying means is applied to the composite waveform at the completion of the acquisitions over the sequential sub-intervals.
